(19) United States
(12) Patent Application Publication
(10) Pub. No.: US 2010/0294354 A1
(43) Pub. Date: Nov. 25, 2010

(54) PATTERNED PHOTOVOLTAIC DEVICES

(75) Inventors: Sergey Frolov, Murray Hill, NJ (US); Michael Cyrus, Summit, NJ (US); Allan James Bruce, Scotch Plains, NJ (US)

Correspondence Address: MAYER & WILLIAMS PC, 251 NORTH AVENUE WEST, 2ND FLOOR, WESTFIELD, NJ, 07090, US

(73) Assignee: Sunlight Photonics Inc., South Plainfield, NJ (US)

(21) Appl. No.: 12/492,244

(22) Filed: Jun. 26, 2009

(51) Int. Cl. H01L 31/00; B26F 1/04

(52) U.S. Cl. 136/256; 234/131; 234/1

(57) ABSTRACT

A patterned photovoltaic device includes at least one photovoltaic cell, at least one carrier substrate attached to the cell, and at least one opening extending through the cell and the carrier substrate.

### FIELD

The following relates generally to photovoltaic devices, and more particularly to patterned photovoltaic devices and methods of producing the same.

### RELATED ART

Renewable energy, unlike conventional energy, is generated by harnessing one or more potentially limitless supplies of naturally replenished natural resources, including, for example, sunlight, wind, rain, tides and geothermal heat. Because of being generated as such, a significant portion of the world's population realizes that renewable energy is ever increasing in importance because, for example, renewable energy provides ways to supplant or augment conventional energy and/or to provide energy where conventional energy does not exist or cannot be distributed.

Given that most sources of renewable energy are environmentally clean, many consider renewable energy as a way of reducing detrimental effects to the environment (e.g., pollution, and in turn, global climate change) caused by generating conventional energy from fossil fuels. And given an ever decreasing supply of the fossil fuels and concerns over peak oil, many believe that, in the near future, the sources of renewable energy need not only to increase in amount, but also proliferate in type.

In addition, certain renewable-energy sources may spur development of new applications and/or cause re-development of existing applications to take advantage of such sources. For example, some of the renewable-energy sources may have an inherent characteristic of being able to provide power without being tethered to a remote distribution center. This characteristic may spur development of mobile and/or wireless applications, for example. Moreover, renewable energy may allow for deployment of certain types of applications that, but for a given type of source, would not be practicable.

Major contributors to current, worldwide generation of renewable energy are renewable-energy sources that employ a photovoltaic (PV) effect. Each of these PV-based renewable-energy sources (PV source) generates energy, in the form of electricity, by harnessing electromagnetic radiation, such as sunlight. Many applications for the PV source currently exist. These applications are not limited to any particular area of the world and/or any given sector of economy. In remote regions of the world, for example, an off-grid installation of the PV source provide the only available source of electricity. In highly populated and/or economically developed regions, the PV source may, for example, source electricity to an electrical grid to supplement and/or reduce the amount of conventional energy distributed from the electrical grid. Assuming that a cost per unit of energy provided from the PV source is less than a cost per unit of energy provided from a source of conventional energy, any savings in costs resulting from the PV source sourcing electricity to the electrical grid may be realized by utility companies and passed on to their customers.

To facilitate the foregoing in the past, a legacy PV source employs either a legacy PV panel or a legacy array of such PV panels. Each of the legacy PV module and legacy photovoltaic-panel array typically includes a plurality of legacy PV cells (sometimes referred to as solar cells) that are electrically interconnected. Each of these legacy PV cells is constructed without special regard to the esthetic appearance of these legacy PV devices. The construction of the legacy PV cells, each of the legacy PV module and legacy photovoltaic-panel array is generally basic and not aimed to produce any specific visual impression. Likewise, legacy PV production methods also lack the ability to produce PV devices with complex visual patterns that may provide additional appeal to end users.

As can be readily discerned from the foregoing, the legacy PV source is not suitable for new applications that require renewable-energy sources with specific artistic appearance. Therefore, there is a need in the art for a PV source and corresponding methods of production suitable for such applications.

### SUMMARY

In accordance with one aspect of the invention, a patterned photovoltaic device is provided. The device includes at least one photovoltaic cell, at least one carrier substrate attached to the cell, and at least one opening extending through the cell and the carrier substrate.

In accordance with another aspect of the invention, a punching apparatus for producing openings in patterned photovoltaic cells is provided. The apparatus includes at least one blanking die and at least one pressure pad to hold photovoltaic cells and at least one puncher to produce openings. The apparatus also includes a positioning stage to move and align the cells to the puncher and a punch controller to control the punching process.

In accordance with yet another aspect of the invention, a method is provided for producing a patterned photovoltaic device comprising steps of producing a photovoltaic cell, attaching the cell to a carrier substrate, and producing at least one opening that extends through the cell and the carrier substrate.

### BRIEF DESCRIPTION OF DRAWINGS

FIG. 1 shows a patterned photovoltaic (PV) device that includes multiple openings.

FIG. 2 shows a cross-section through one example of a PV cell.

FIG. 3 shows a cross-section through one example of a PV cell that includes an opening.

FIG. 4 shows an example of a process flow for manufacturing a patterned PV device.

FIGS. 5A and 5B show an example of a punching apparatus that may be used to produce the openings in PV cells.

FIG. 6 shows another example of a process flow for manufacturing a patterned PV module.

FIG. 7A shows one example of a text-based company logo that is formed on a PV cell 710 from a pattern of punched holes.

FIG. 7B shows an example of a pattern layout for a company logo that avoids any intersection with the metal contact grid that is deposited on the cell.

FIG. 8 shows an artistic graphical pattern formed from a series of round openings with different sizes and varying densities, which collectively creates a picture of clouds in the sky.

FIG. 9 illustrates an example of a computerized punching process for an arbitrary pattern.

FIG. 10 shows a cross-section of an encapsulated patterned PV device 1000 that includes at least one patterned PV cell sandwiched between two cover sheets.

FIG. 11 shows a patterned PV device that includes at least one cover sheet and nine patterned PV cells that are electrically interconnected using conducting tabs.

FIG. 12 shows an example of a window-mounted patterned solar panel.

FIG. 13 shows the inside of a building wall having a plurality of windows that include multiple patterned PV devices mounted therein.

### DETAILED DESCRIPTION

In the following detailed description, numerous specific details are set forth in order to provide a thorough understanding of exemplary embodiments or other examples described herein. However, it will be understood that these embodiments and examples may be practiced without the specific details. In other instances, well-known methods, procedures, components and circuits have not been described in detail, so as not to obscure the following description. Further, the embodiments disclosed are for exemplary purposes only and other embodiments may be employed in lieu of, or in combination with, the embodiments disclosed.

In accordance with the present invention, FIG. 1 shows a patterned photovoltaic (PV) device 100 comprising at least one PV cell 110 having at least one opening 120. PV cell 110 is in turn composed of substrate 111, back contact 112, 1^{st} semiconductor layer 113, 2^{nd} semiconductor layer 114, top contact 115 and secondary carrier substrate 130. Additional layers, not shown, may also include electrical buffer layers, optical coatings, metal grids and others. Alternatively, PV cell 110 may be produced in a superstrate configuration having a similar cross-section to that of FIG. 1, in which there may be superstrate 111, top contact 112, 1^{st} semiconductor layer 113, 2^{nd} semiconductor layer 114 and back contact 115. In the substrate configuration shown in FIG. 1 the light is directed onto device 100 from the top, whereas in the superstrate configuration the light is directed from the bottom through the superstrate. 1^{st} semiconductor layer 113 may be for example a p-type semiconductor layer and 2^{nd} semiconductor layer 114 may be an n-type semiconductor layer. Layers 113 and 114 may be produced from the same basic material (e.g. a-Si), so that a p-n homo-junction is formed at their interface. Alternatively, layers 113 and 114 may be produced from different semiconductor materials (e.g. CIGS and CdS), so that a p-n hetero-junction is formed at their interface. Other varieties of PV cells may be used as well, including p-i-n junctions, MIS junctions, Graetzel-type cells and the like.

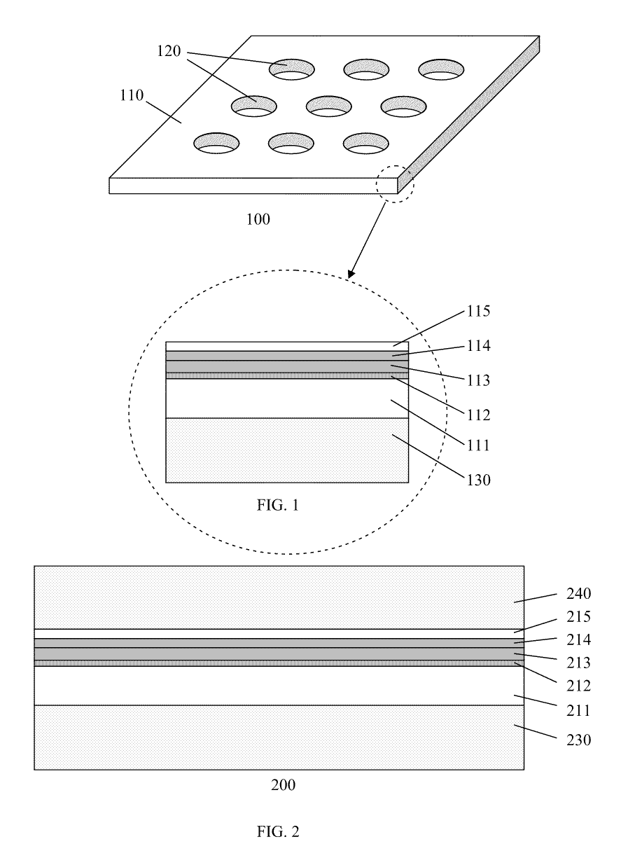

PV cell 110 also comprises at least one secondary carrier substrate 130, which may be attached to the substrate 111, as shown in FIG. 1. Alternatively, secondary substrate 130 may be attached to the top contact 115, in which case substrate 130 must be at least partially transparent. Furthermore, two secondary substrates may be used in producing a patterned PV device 100. FIG.2 shows a PV cell 200 consisting of substrate 211, back contact 212, 1^{st} semiconductor layer 213, 2^{nd} semiconductor layer 214, top contact 215, bottom secondary substrate 230 and top secondary substrate 240. Further additional secondary substrates may be attached to PV cell 200.

PV cell 110 is preferably a thin-film PV cell, in which substrate 111 is a thin flexible substrate, such as polyimide film, aluminum foil, stainless steel sheet or other similar thin sheet-like material. Substrate thickness may be in the range of 12- 100 microns, preferably 25-50 microns. PV cell 110 may be amorphous silicon (a-Si) cell, in which layers 113 and 114 are p-type and n-type doped a-Si layers, respectively. Also, PV cell 110 may be a CIGS (Cu—In—Ga—Se) cell, in which layers 113 and 114 are p-type CIGS and n-type CdS layers, respectively. Total thickness of semiconductor layers may be in the range of 0.1-20 microns, preferably in the range of 1-3 microns. The back contact 112 may be a Mo layer with thickness in the range of 0.5-1 microns, and the top contact may be Al-doped ZnO layer with thickness in the range of 0.2-1 microns. PV cell 110 may include additional semiconductor layers and corresponding p-n junction, which may form a multi-junction PV cell. For example, a-Si tandem cell may be produced by stacking top and bottom a-Si single junction cells, in which the semiconductor bandgap of the top cell is larger than that of the bottom cell.

Secondary substrate 130 may be glued, laminated or otherwise attached to the bottom side of substrate 111. Secondary substrate 130 may be a plastic film, flexible or rigid, with thickness in the range from 25 microns to 5 mm. Appropriate plastic materials may include polyimide, polyethylene, polystyrene, polyvinyl chloride and others. Substrate 130 may be laminated to substrate 111 using silicone or ethylene vinyl acetate (EVA).

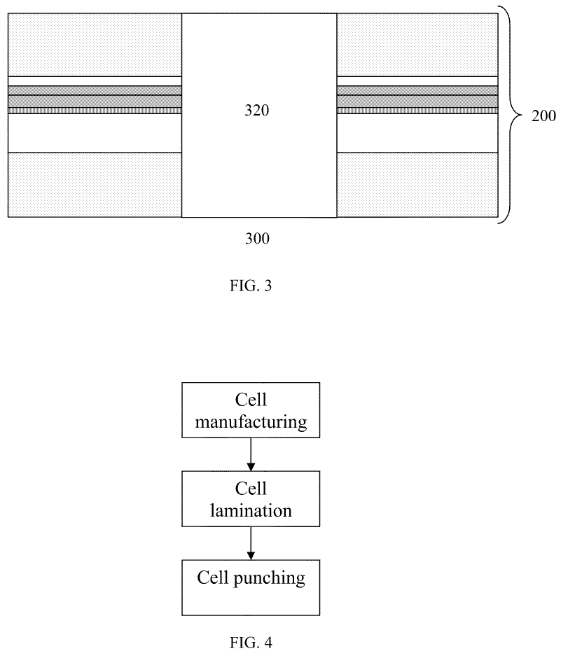

PV device 100 may be patterned, as shown in FIG.1, using a pattern of through holes or openings 120, which may be arranged to produce graphical representations that may or may not convey information to a viewer. For instance, the graphic representations may include text, logos, pictures, and so on, as well as any combination thereof. FIG. 3 shows a cross-section of a patterned PV cell 300 that includes cell 200, in which a through hole 320 has been produced. The shape of the opening 320 may be round, square, polygonal, elliptical or arbitrary. The opening may be produced using laser ablation, dicing saw, blanking punch or other means.

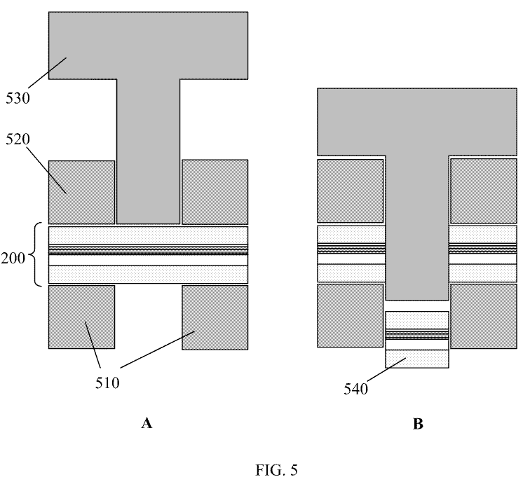

FIG. 4 shows an example of a process flow for manufacturing a patterned PV device. It comprises at least one step of manufacturing a PV cell 410, at least one step of laminating the PV cell to a secondary substrate 420 and at least one step of producing a pattern of openings in the laminated PV cell 420, e.g. using punching. Additional steps may include the reiteration of the described steps and also extra manufacturing steps, such as cell interconnection, modular encapsulation, integration with other electrical components, cell screening, module testing and others.

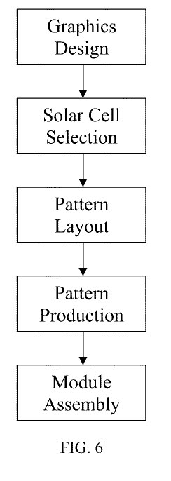

FIG. 5 shows an example of a punching apparatus that may be used to produce openings in PV cells 200. The apparatus includes blanking die 510, pressure pad 520 and puncher 530 (FIG. 5A). The shape and size of opening in the blanking die 510 is close and slightly oversized compared to the shape and size of the puncher tip 530, so that the puncher may enter the opening with very small clearance as shown in FIG. 5B. It may be preferred to have a clearance between the sidewalls of the puncher tip and the opening in the blanking die that is smaller than the thickness of the PV cell 200, in order to minimize burr and fracturing at the edges of opening 320 in the PV cell 200. In this regard, secondary substrate 130 improves mechanical characteristics of thin-film PV device 100, minimizes tensile strain during punching process and minimizes damage to the PV cell, by increasing the overall thickness of the PV device 100.

As a result, a plurality of holes 320 may be produced with the shape and size that closely match those of the puncher tip. Tips of different shapes (round, square, triangular etc.) and sizes (e.g. from 1 mm to 20 mm) may be combined in the same punching machine. In addition, the punching apparatus may include additional holding rings, a press, linear translation stages and a computerized control system. In some cases a single blanking die may contain multiple tips to simultaneously form multiple holes, in some cases perhaps forming a complete pattern at one time. In those cases where it may be impractical to form a complete pattern at once, the puncher may have a “printer head” configuration in which a row of holes is produced at the same time before moving on to the next row in the pattern. One advantage of this approach is that that a single puncher can be used to produce any pattern.

FIG. 6 shows another example of a process flow for manufacturing of a patterned PV module, which includes the steps of graphic design 610, solar cell selection 620, pattern layout 630, pattern production 640 and module production 650.

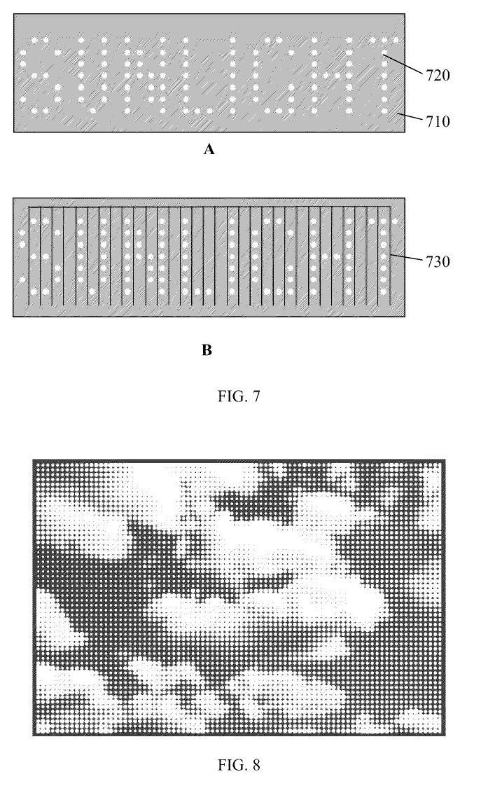

Graphic design step 610 includes the selection of a specific pattern, artistic design and production approach. For example, FIG. 7A shows an exemplary design of a text-based company logo on a PV cell 710, using a pattern of punched holes 720. Solar cell selection may be driven by both customer requirements for specific performance characteristics, such as peak output power, and requirements dictated by the graphic design, such as uniform appearance and compatibility with a specific picture, pattern or other graphic composition. A uniform large-area PV cell, such as PV cell 710, may be the best choice for the graphic design, but it may not be the best choice for achieving the best electrical performance. A better performing PV cell may contain additional surface features, such as metal grid or scribe lines used for monolithic interconnection in monolithically integrated thin-film modules. In such a case, it is preferred to produce such a pattern layout that does not interfere with these surface features. For example, FIG. 7B shows a specific pattern layout for the company logo that avoids any intersection with the metal contact grid 730 deposited on the cell 710.

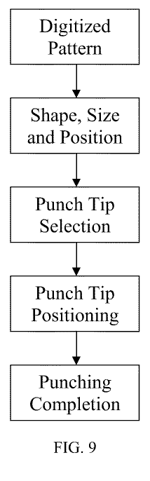

Much more complex graphical or other patterns may be produced using this approach. For example, FIG. 8 shows an artistic graphical design of a through-hole pattern of round openings with different sizes and varying densities that creates a picture of clouds in the sky. The pattern has been generated from an actual photograph of a cloudy sky using a freeware computer program “Rasterbator”. Virtually any graphics, including landscapes and portraits, may be reproduced using a similar design approach.

Pattern production may be accomplished using a number of machining approaches, including punching as discussed above. The punching apparatus may be computer-controlled and programmed to produce complex hole patterns. The computer control may include the selection of the punching tip size, accurate positioning of the puncher above the PV device and monitoring of critical processing parameters, such as PV device position and punching speed. FIG. 9 illustrates an example of a computerized punching process for an arbitrary pattern. The pattern is first digitized in step 910 to produce shapes, sizes and positions of all or some openings in a given graphic design. Second, in step 920, the shape, size and relative position of the openings are sequentially provided to the punch controller. Third, in step 930, the controller in the punching machine selects the punch tip with the requested shape and size. Fourth, in step 940 the linear translation stage moves the puncher to the requested position and fifth, in step 950 the puncher produces an opening and completes the sequence. This process may be repeated until all required openings are produced. In each given sequence shown in FIG. 9 one or more openings may be produced simultaneously.

Module production may include steps of encapsulation, electrical interconnection and others. For example, FIG. 10 shows a cross-section of an encapsulated patterned PV device 1000, which includes at least one patterned PV cell 300. The cell 300 may be sandwiched between cover sheets 1010 and 1020. These cover sheets may be transparent and produced from thin glass panels having thickness in the range of 0.5 to 5 mm. Alternatively, these cover sheets may be transparent and produced from plastic films having thickness in the range of 0.1 to 5 mm. In the latter case these cover sheets may be also flexible, so that the whole PV device 1000 may be flexible too. The attachment or lamination of the cover sheets 1010 and 1020 to the cell 300 may be achieved using silicon or EVA.

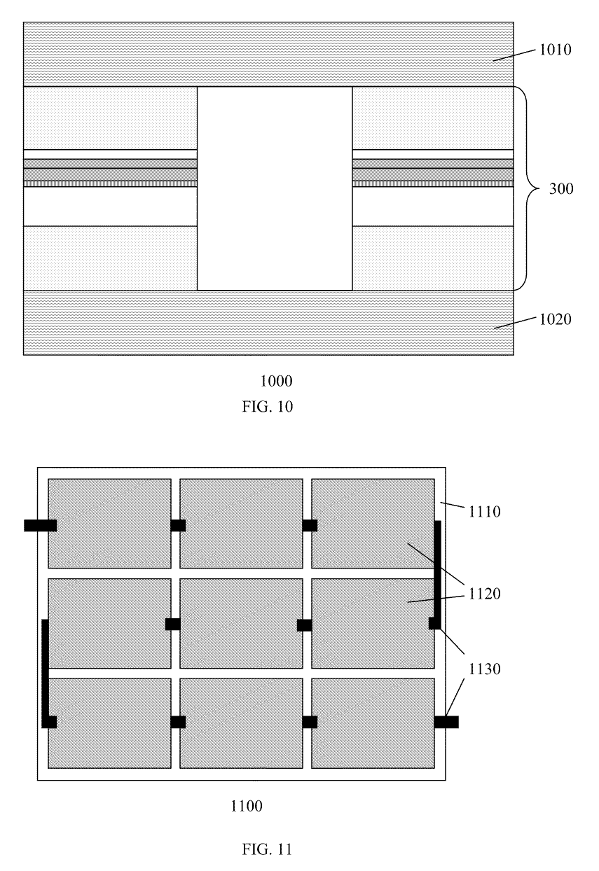

Steps of electrical interconnection may be required for providing external contacts to the patterned PV device and internal interconnection between individual PV cells in the case when such a PV device is composed of multiple PV cells. FIG. 11 shows a patterned PV device 1100 composed of at least one cover sheet 1110 and nine patterned PV cells 1120 that are electrically interconnected using conducting tabs 1130. PV cells 1120 may have the same pattern or different patterns; in the latter case PV cells 1120 may be arranged relative to each other to provide a coherent overall pattern.

In accordance with one aspect of the present invention, a patterned PV device may be mounted and used in a window of a building, where it may serve a dual purpose of reducing the amount of light transmitted in either direction (from inside or outside) and converting part of the absorbed light energy into electricity. The graphic design of a pattern on such a device may be aesthetically pleasing and/or informative to people observing it either from inside or outside of a building or both, which may provide additional motivation for using such environmentally friendly devices in a given building. For instance, windows containing picture-like PV modules may be more pleasing than blank windows to occupants of a building, whereas window or wall-mounted patterned PV modules with company logos that can be seen from the outside of a building may be attractive for their advertising appeal. In the latter case, a patterned PV module may be backlit with artificial light, e.g. incandescent or LED light, so that produced patterns are easily visible at nighttime. The light source may be powered by the PV module itself or rechargeable batteries connected to the same PV module.

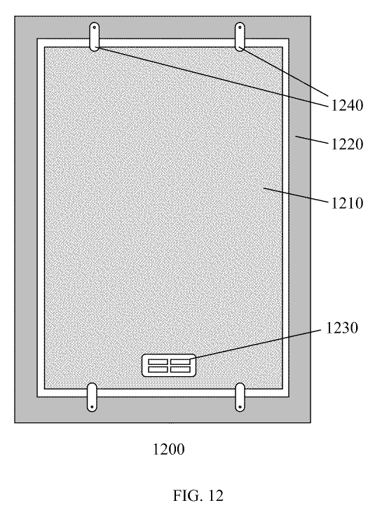

FIG. 12 shows an example of a window-mounted patterned solar panel 1200, which primarily consists of a patterned PV device 1210. PV device 1210 may be positioned inside the window frame 1220 and held in place by clamp 1240. As an example, a battery charger 1230 may be attached to the PV device 1210 and electrically connected to its output terminals; such a charger may be used to recharge batteries, cell phones, iPods and other portable devices using solar power alone. PV device 1210 may be rigid; it may be attached to the window glass sheet on the inside or the outside of the window, or alternatively, it may be used to replace one or more window glass sheets. PV device 1210 may be flexible, in which case it may be attached or glued directly onto the window glass without the use of clamps 1240.

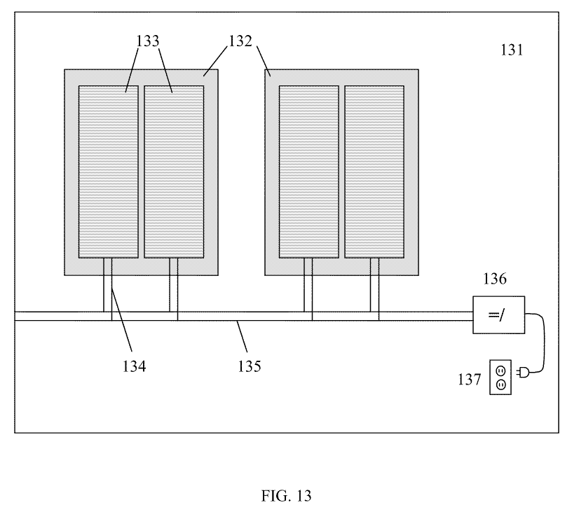

FIG. 13 shows the inside of a building wall 1310 and a plurality of windows 1320. Multiple patterned PV devices 1330 may be mounted onto windows 1320, absorbing a portion of the sunlight energy and converting it to electricity. The remaining portion of the sunlight may be used for lighting the inside of a building. PV devices 1330 may be grouped, so that electrical terminals of each device 1330 are connected to the common bus 1350. The connection may be done in parallel (as shown in FIG. 13) or in series. The common bus may be in turn connected to the electrical inverter 1360, which transforms the direct current provided by the PV devices 1330 into an alternating current. The output of the inverter may then be connected to the electrical grid 1370, thus reducing the overall electrical consumption in the building.

Overall, there may be a wide range of applications available to patterned PV devices provided by this invention. These include stand-alone electrical components, e.g. recharging stations for mobile electrical devices, or pluggable PV devices that may be plugged into existing grid in order to reduce overall power consumption. Apart from better energy utilization, these devices may provide additional benefits that include reducing average temperature inside the building by absorbing excess sunlight, improving interior design by providing picture-quality PV devices, advertising revenues from externally mounted patterned PV devices and many others.

1. A patterned photovoltaic device comprising
at least one photovoltaic cell,
at least one carrier substrate attached to said cell,
at least one opening through said at least one cell and at least one carrier substrate.

2. Device of claim 1 wherein said at least one opening allows at least partial transmission of incident light.

3. Device of claim 1 wherein said at least one opening includes a plurality of openings.

4. Device of claim 3 wherein said plurality of openings are arranged in a pattern producing a graphical representation conveying information to a viewer.

5. Device of claim 1 further comprising electrical terminals connected to said at least one photovoltaic cell.

6. Device of claim 5 further comprising a charger connected to the output terminals.

7. Device of claim 5 further comprising an inverter connected to the output terminals.

8. Device of claim 1 wherein said at least one photovoltaic cell is at least one flexible photovoltaic cell.

9. Device of claim 1 wherein said at least one opening is produced by punching.

10. Device of claim 1 further comprising at least one cover sheet attached to said at least one carrier substrate.

11. Device of claim 4 wherein the graphical representation includes text.

12. Device of claim 4 wherein the graphic representation includes a picture.

13. A punching apparatus for producing openings in patterned photovoltaic cells comprising:
at least one blanking die and at least one pressure pad to hold photovoltaic cells;
at least one puncher to produce openings;
a positioning stage to move and align the cells to the puncher;
a punch controller to control the punching process.

14. Apparatus of claim 13 wherein at least one puncher is a plurality of punchers.

15. Apparatus of claim 14 wherein plurality of punchers includes punchers of at least two different sizes.

16. Apparatus of claim 14 wherein plurality of punchers includes punchers of at least two different cross-sections.

17. Apparatus of claim 13 further comprising digital data containing positions, shapes and sizes of opening to be produced on said photovoltaic cells.

18. A method of producing a patterned photovoltaic device comprising steps of
producing a photovoltaic cell;
attaching the cell to a carrier substrate;
producing at least one opening through the cell and the carrier substrate.

19. Method of claim 18 wherein at least one opening is produced by punching.

20. Method of claim 20 wherein said at least one opening includes a plurality of openings arranged in a pattern producing a graphical representation conveying information to a viewer.
